(19) United States
(12) Patent Application Publication
(10) Pub. No.: US 2014/0318622 A1
(43) Pub. Date: Oct. 30, 2014

(54) CONCENTRATOR PHOTOVOLTAIC SYSTEMS

(71) Applicant: ON-SUN SYSTEMS LIMITED, Birmingham (GB)

(72) Inventor: John-Paul Szczepanik, Defford (GB)

(73) Assignee: ON-SUN SYSTEMS LIMITED, Birmingham (GB)

(21) Appl. No.: 14/363,520

(22) PCT Filed: Dec. 7, 2012
(86) PCT No.: PCT/GB2012/053048

§ 371 Date: Jun. 6, 2014

(30) Foreign Application Priority Data
Dec. 7, 2011 (GB) 1121032.5

(51) Int. Cl. H01L 31/042; F16M 13/00; F16M 11/18

(52) U.S. Cl. CPC H01L 31/0422; F16M 11/18; F16M 13/00
USPC 136/259; 248/125.7

(57) ABSTRACT

A support for a photovoltaic element comprising at least a primary optical component and a photovoltaic package. The support comprises at least one clip for holding the primary optical component, at least one holder configured to locate the photovoltaic package, and at least one cut-out portion to allow overlap with the primary optical component of an adjacent photovoltaic element when the elements are rotated to align with incident sunlight.

The present invention relates to concentrator photovoltaic systems including a plurality of elements and, in particular, to supports configured to hold the constituent parts of an element.

The elements that make up a concentrator photovoltaic system typically include a photovoltaic package and at least one optical component configured to focus sunlight onto a photovoltaic cell contained within the photovoltaic package in order to produce electricity. In order for the element to optimise capture of solar energy, at least part of the system typically tracks the sun. Depending on the tracking system, this may occur as a result of movement of the entire system relative to a fixed support such as a wall or roof of a building. Alternatively, each of the plurality of elements may be configured to track the sun by moving relative to one or more support members. If the elements are movable, then it is important that as they track the sun, the optical components remain correctly aligned.

An example of a concentrator photovoltaic system that tracks the sun is given in WO 2009 063231. The system comprises first and second support members provided in two separate and substantially parallel planes; and at least one light receiving element supported on each support member across the gap between the two planes by one or more resilient flexible beams which elastically deform upon relative translational displacement of the first and second support members.

Typically, concentrator photovoltaic systems comprise a large number of elements and therefore the individual elements are often quite small. In order to achieve effective collection of solar energy, the components within the element must be closely packed, or tessellated, to maximise the amount of light collected over a given area and correctly aligned to the sun.

The present invention has been made in light of the above mentioned constraints.

According to the present invention there is provided a support for a photovoltaic element comprising at least a primary optical component and a photovoltaic package, the support comprising: at least one clip for holding the primary optical component, and at least one holder configured to locate the photovoltaic package, and at least one cut-out portion to allow overlap with the primary optical component of an adjacent photovoltaic element when the elements are rotated to align with the incident sunlight. This cut-out portion may have a U-shaped cross section and may be integrally formed with the support as a whole. The provision of a cut-out portion enables adjacent elements within a concentrator photovoltaic system to be closely packed maximising the proportion of the available incident light that can be collected. If the cut-out portion were not provided then adjacent elements would either have to be sufficiently widely spaced that they did not foul one another or alternatively, the angle of rotation of the element to track the sun would be limited. In both of these scenarios, some light incident on the system would not be incident on one of the elements, thus reducing the efficiency of the system and potentially resulting in unwanted solar heating of some of the components.

The clip for holding the primary optical component may be configured to provide a snap-fit connection with the primary optical component. This may be achieved by providing a substantially U-shaped profile. The U-shaped clip provides a single correct position of the primary optical component. As a result of this, the precision of positioning of the primary optical component is dictated solely by the accuracy of the manufacture of the support. The support is preferably manufactured by a stamping process, which is highly accurate. The provision of a snap-fit connection also minimises both the total number of components required and also the number of movable components. This results in a support that is both cost effective and accurate.

The support may further comprise at least one protrusion for holding a secondary optical component. The protrusion has a location feature that provides a snap fit connection for the secondary optical component.

The support may be formed of more than one leg, for example two, three or four legs each of which may be provided with at least one clip for holding the primary optical component, and at least one holder configured to locate the photovoltaic package. A three-legged configuration results in a very stable support.

Each leg may further comprise a box section, i.e. a section that is elongate in the radial direction of the primary optical component. Each leg may then be attached to the adjacent leg via the box section, which may be substantially rectilinear. By minimising the lateral extent of the legs other than the box section, the amount of light lost into the legs is reduced, thus maintaining the efficiency of the element as a whole. The box section may be positioned below the secondary optical component so that the cone of rays emerging from the secondary optical component does not overlap with the box section at all considerably reducing the energy lost into the support, whilst simultaneously providing a robust support.

The support may be formed from a single piece manufactured by stamping then folding. Known stamping technologies are extremely accurate and repeatable and the folding required is parallel to the optical axis of the element and therefore the alignment of the optical components in use can be accurately determined using supports manufactured in this way.

The support may be incorporated into a photovoltaic element comprising at least a primary optical component, a photovoltaic package and a heat sink. The support may be thermally and electrically isolated from the heat sink. The support does not provide any heat transfer function and it is therefore important that it does not communicate heat to the rest of the element. The support is configured to hold the primary optical component and the photovoltaic package in such a way that light incident on the primary optical component enters the photovoltaic package. The primary optical component may achieve this by focussing the light on the photovoltaic package. Alternatively, the focal point of the primary optical component may not be coincident with the photovoltaic package. However, in this case, substantially all of the cone of rays emerging from the primary optical component should be incident on the photovoltaic package. The photovoltaic element may further comprise an insulating ring.

The present invention will now be described, by way of example only, with reference to the accompanying drawings in which:

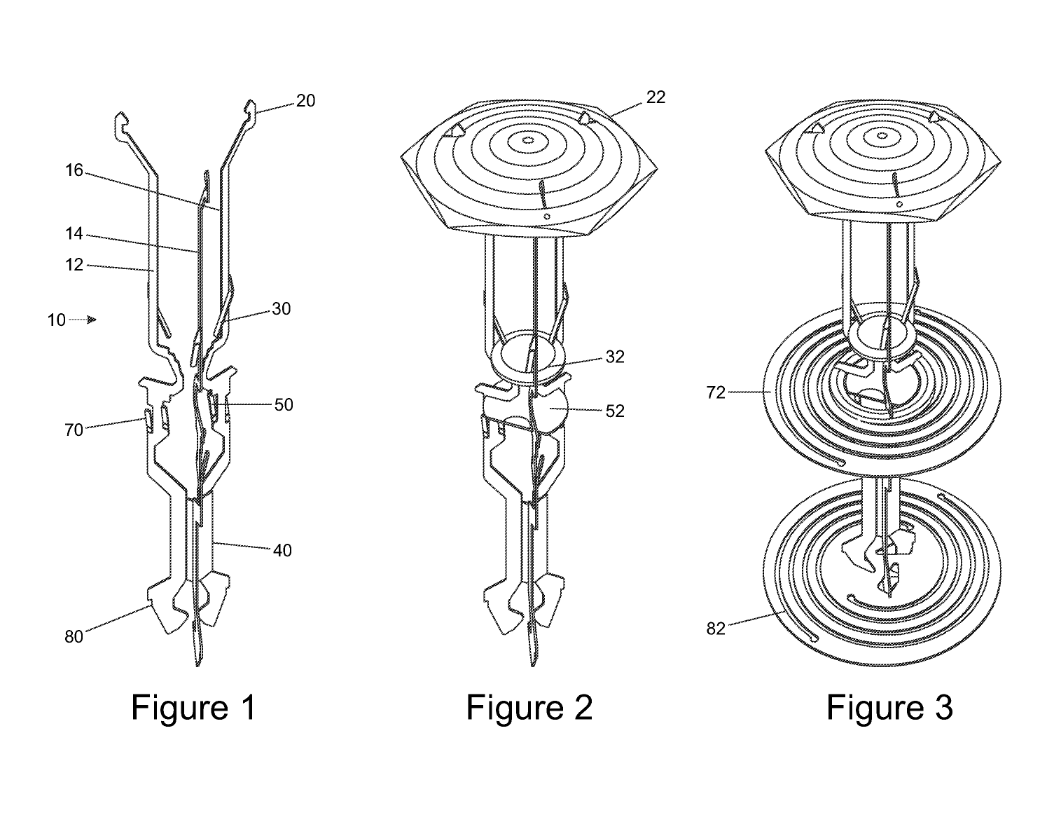

FIG. 1 shows a support according to the present invention,

FIG. 2 shows the support of FIG. 1 in a part assembled form,

FIG. 3 shows an element including the support of FIG. 1,

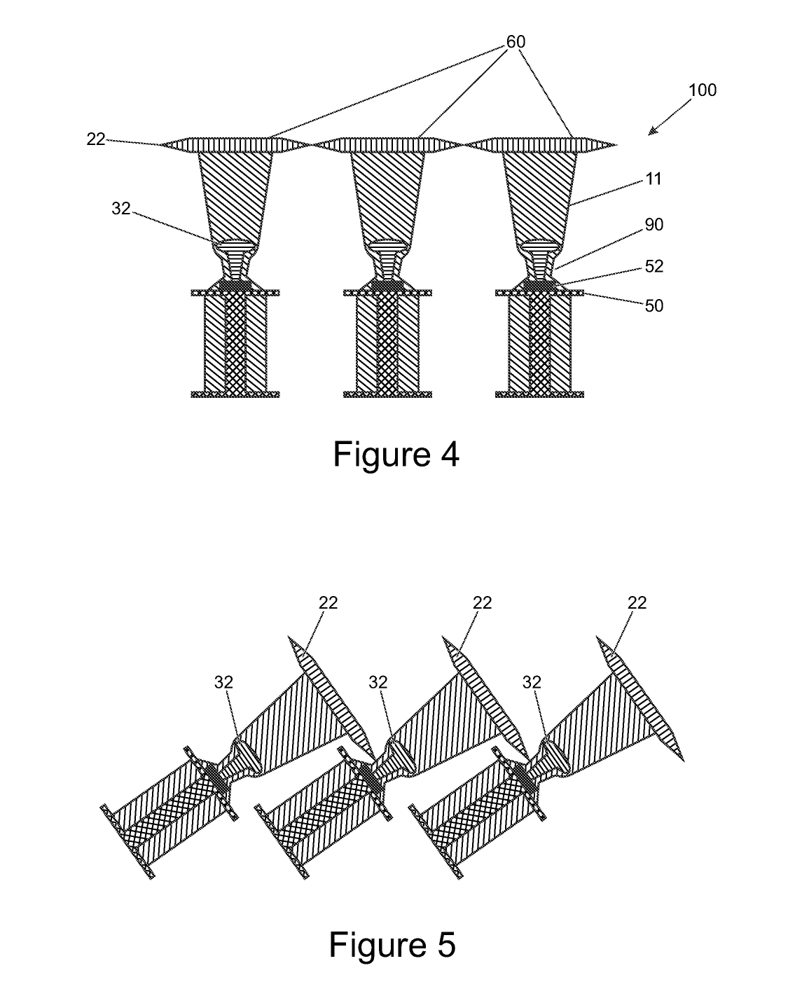

FIGS. 4 and 5 show part of a concentrator photovoltaic system incorporating a number of elements as shown in FIG. 3,

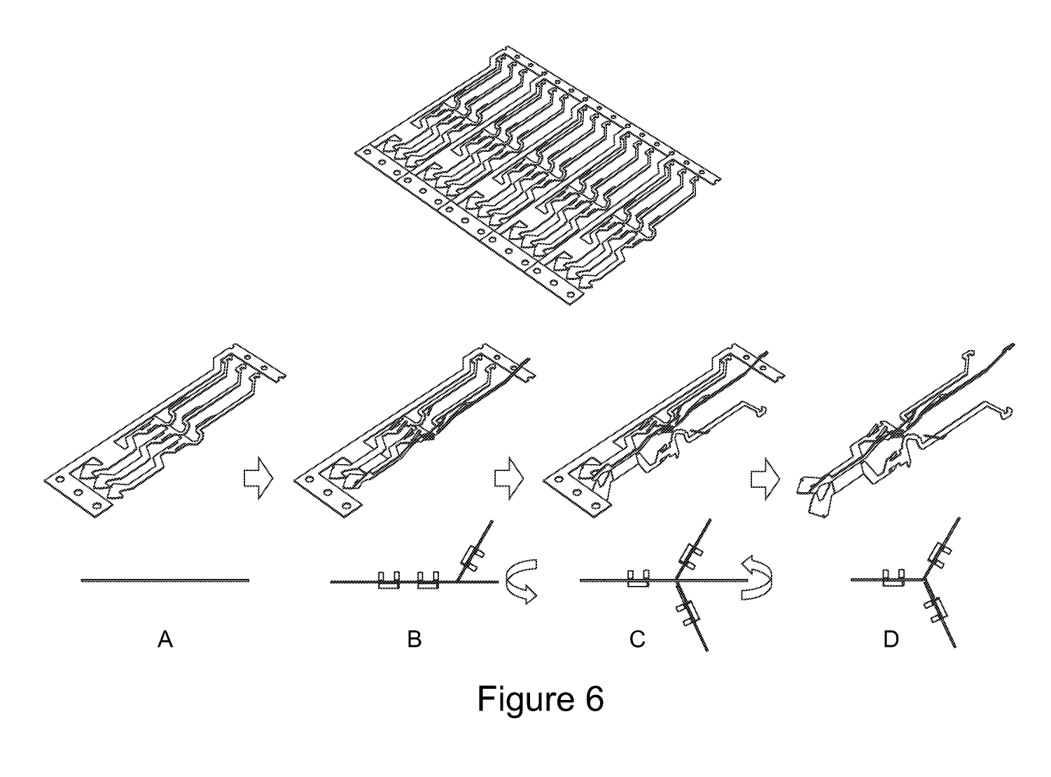

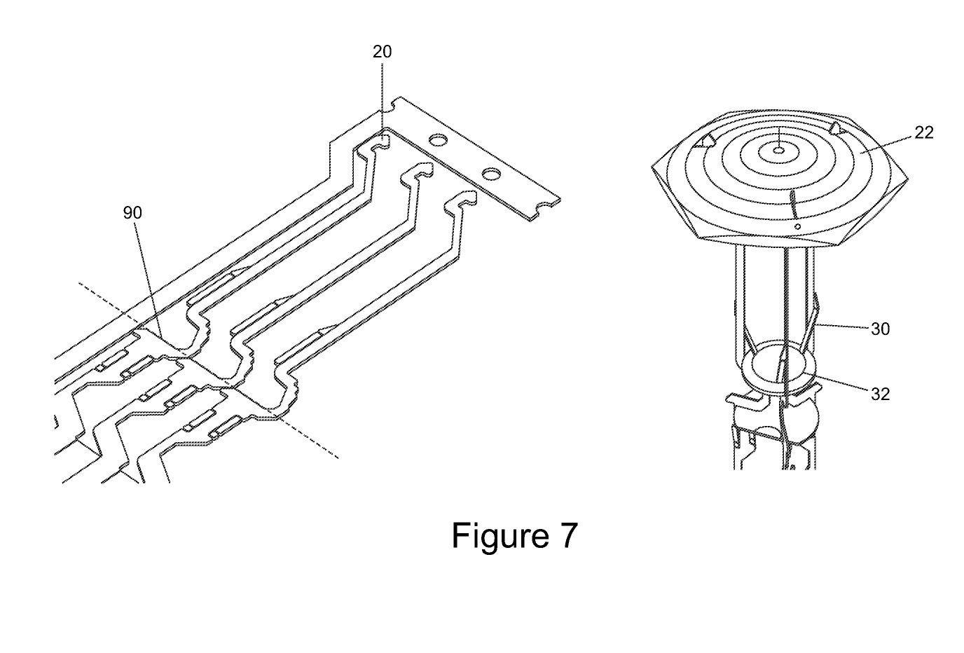

FIGS. 6A to 6D show the manufacturing steps of the support of FIG. 1,

FIG. 7 shows detail of the interface between the support of FIG. 1 and a primary optical component,

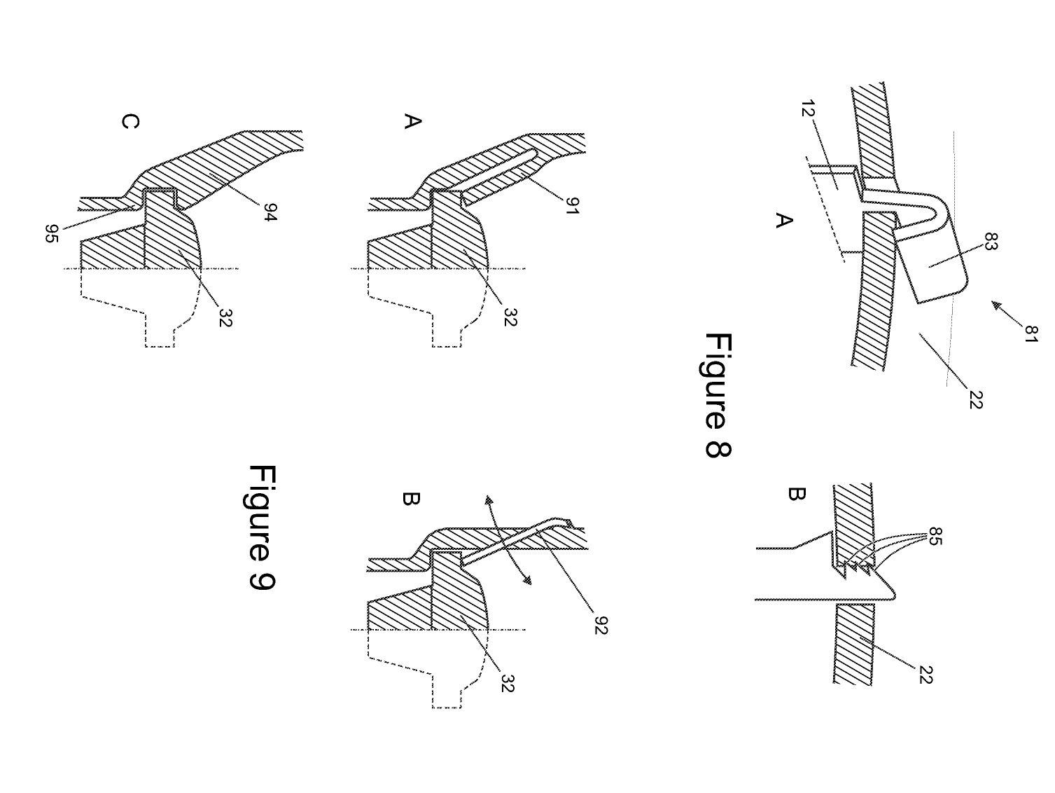

FIGS. 8A and 8B show alternative configurations of a clip for holding the primary optical component, and

FIGS. 9A to 9C show alternative configurations of a protrusion for holding a secondary optical component.

FIG. 1 shows a support 10 according to the present invention. The support 10 comprises three legs 12, 14, 16. The legs 12, 14, 16 are elongate and each leg is provided with a clip 20 for holding a primary optical component 22, a protrusion 30 for holding a secondary optical component 32, a box section 40 and a holder 50 configured to locate a photovoltaic package 52.

When the primary optical component 32, secondary optical component 32 and photovoltaic package 52 are attached to the support 10 as shown in FIG. 2, all of the light incident on the primary optical component 22 is incident on the secondary optical component 32 and is subsequently incident on the photovoltaic package 52.

As shown in FIG. 3, the support 10 holds the optical components 22, 32 and photovoltaic cell 52 to form a complete sub-assembly 60. This sub-assembly 60 can then be inserted into a concentrator photovoltaic system 100 (CPV) and mounted such that the motion system can rotate the complete sub-assembly 60 to track the sun. In order for the sub-assembly 60 to interface with a CPV system as described in WO 2009 063231, the legs 12, 14, 16 are each provided with two indentations 70, 80. The upper indentation 70 is just below the protrusion 30 for the secondary optical component and provides connection with a top sheet 72. The lower protrusion 80 is provided on the outer surface of the holder 50 and provides connection with a bottom sheet 82.

FIG. 4 shows three sub-assemblies 60 arranged in a CPV 100. Obviously, the CPV 100 is shown only in part, for clarity. The full CPV comprises an array of sub-assemblies arranged in a matrix or grid formation. The grid may comprise 100, 1000 or more elements. The area swept out by the legs is shown as a hatched area. As the sub-assemblies 60 rotate to track the sun they move from the configuration shown in FIG. 4 into that shown in FIG. 5. As is apparent from FIG. 5, the primary optical component 22 of each sub-assembly 60 overlaps with the adjacent sub-assembly 60 when the sub-assemblies are rotated to their maximum steering angle of 60°. In order to avoid contact between the primary optical component 22 and the support 10, each leg 12, 14, 16 of each support 10 has a cut-out portion 90 to accommodate the primary optical component 22 of the adjacent sub-assembly 60. In the illustrated example, the cut-out portion 90 is C-shaped, although the shape can be selected to accommodate the lens shape. For example, a Fresnel lens would have a more constant cross sectional area than a standard convex lens and therefore the shape of the cut-out portion 90 would be more elongate for a Fresnel lens and more rounded or open for a standard lens.

The support 10 is made from a single piece of sheet metal that is formed by stamping. Stamping can be carried out very accurately and repeatably over a high volume of production. This piece is folded to form a tripod arrangement as shown in FIGS. 6A to 6D. Whilst the folding step is accurate, it is also important to note that the folding is perpendicular to the optical axis of the sub-assembly 60 and therefore any tolerances in the fold will have a negligible effect on the relative positions of the optical elements and the photovoltaic package. Any errors in the fold are reduced by a factor of three because of the nature of the legs being positively spring inwards.

FIG. 7 shows further detail of the clips 20 used to affix the primary optical component 22. In order to maximise the light collected by the CPV system 100 as a whole, the attachment to the primary optical component 22 occurs within the perimeter of that component. FIG. 7 shows that the primary optical component 22 is clasped by the clips 20 on the three legs 12, 14, 16 using three corresponding slots in the primary optical component.

FIGS. 8A and 8B show alternative clips for affixing the primary optical component 22. FIG. 8A shows a folded clip 81 which comprises an elongate tab 82 that protrudes from the leg 12. The tab 82 is folded to create a catch 83 that locks the primary optical component 22 in place. The primary optical component can be pushed along the tab 82 thus depressing the catch 83 and once past the catch 83, the catch 83 springs back locking the primary optical component in place.

FIG. 8B shows a barbed clip 84 comprising three barbs 85 that are configured to lock the primary optical component in place. Although FIG. 8B shows three barbs, it will be apparent that the number of barbs may be altered and the clip 84 may comprise one, two, four or more barbs depending on the size and shape of the primary optical component.

FIGS. 9A to 9C show alternative protrusions for affixing the secondary optical component 32. FIG. 9A shows a protrusion that is formed from a sprung finger 91 that extends parallel to the leg 14. When pressure is exerted on the finger 91 in can deflect until it touches the leg or it may deflect perpendicular to the axis of the leg. This movement of the finger 91 enables the secondary optical component 32 to be pushed past the finger 91. Once the secondary optical component has moved past the finger 91, the finger 91 will spring out to be parallel with the leg 14 and thus retain the secondary optical component 32.

FIG. 9B shows a non-axial finger 92 which is elongate and protrudes perpendicular to the leg 14 at the point of connection thereto. The finger 92 folds substantially at the point of connection to the leg 14 and has a considerable degree of freedom of movement enabling rotation in at least two planes namely substantially clockwise and downwards as illustrated in FIG. 9B. The finger 92 operates in a similar fashion to the finger 91 described above with reference to FIG. 9A in that it deforms to allow the secondary optical component to be positioned and then the finger 92 springs back to its original position, thereby holding the secondary optical component 32 in place.

FIG. 9C shows a U-shaped clip 93 which comprises two lips 94, 95 that protrude from the leg 16 in a position suitable for holding the secondary optical component 32. In contrast to the protrusions illustrated in FIGS. 9A and 9B, the protruding lips 94, 95 do not deform, rather the leg 16 itself deforms in order to accommodate the secondary optical component 32. Once the secondary optical component 32 has passed over the upper lip 94, the leg returns to its unstressed position. The secondary optical component 32 is thereby held between the lips 94, 95.

As a result of the support 10 residing within the optical path of the incident light, the support will inevitably shade some of the light from the cell and thereby reduce the overall efficiency of the sub-assembly 60. The support 10 is made from metal so that the extent of the support in the radial direction is minimised, thereby minimising the shading. A further factor that reduces the shading is the provision of the box-section 40 between the secondary optical component 32 and the photovoltaic package 50.

1. A support for a photovoltaic element comprising at least a primary optical component and a photovoltaic package, the support comprising:
at least one clip for holding the primary optical component,
at least one holder configured to locate the photovoltaic package, and
at least one cut-out portion to allow overlap with the primary optical component of an adjacent photovoltaic element when the elements are rotated to align with incident sunlight.

2. The support according to claim 1, wherein the cut-out portion has a U-shaped cross section.

3. The support according to claim 1, wherein the cut-out portion is integrally formed.

4. The support according to claim 1, wherein the clip for holding the primary optical component is configured to provide a snap-fit connection with the primary optical component.

5. The support according to claim 4, wherein the clip for holding the primary optical component has a substantially U-shaped profile in order to provide the snap-fit connection.

6. The support according to claim 1, further comprising at least one protrusion for holding a secondary optical component.

7. The support according to claim 6, wherein the protrusion is configured to deform in order to accommodate the secondary optical component.

8. The support according to claim 1, wherein the support is formed of more than one leg.

9. The support according to claim 8, wherein the support is formed of three legs.

10. The support according to claim 8, wherein each leg comprises at least one clip for holding the primary optical component, and at least one holder configured to locate the photovoltaic package.

11. The support according to claim 8, wherein each leg further comprises a box section and wherein each leg is attached to the adjacent leg via the box section.

12. The support according to claim 11, wherein the box section portion is substantially rectilinear.

13. The support according to claim 1, being formed from a single piece manufactured by stamping then folding.

14. A photovoltaic element comprising at least a primary optical component, a photovoltaic package and a heat sink, and a support according to claim 1.

15. The photovoltaic element according to claim 14, wherein the support is thermally and electrically isolated from the heat sink.

16. The photovoltaic element according to claim 14, further comprising an insulating ring.
